(19) United States
(12) Patent Application Publication
(10) Pub. No.: US 2015/0016879 A1
(43) Pub. Date: Jan. 15, 2015

(54) FASTENING DEVICE FOR BACKPLANE

(71) Applicants: HON HAI PRECISION INDUSTRY CO., LTD., New Taipei (TW); HONG FU JIN PRECISION INDUSTRY (ShenZhen) CO., LTD, Shenzhen (CN)

(72) Inventors: XIAO-GANG YIN, Shenzhen (CN); JUN-HUI WANG, Shenzhen (CN)

(73) Assignees: HON HAI PRECISION INDUSTRY CO., LTD., New Taipei (TW); HONG FU JIN PRECISION INDUSTRY (ShenZhen) CO., LTD, Shenzhen (CN)

(21) Appl. No.: 14/037,383

(22) Filed: Sep. 26, 2013

(30) Foreign Application Priority Data
Jul. 10, 2013 (CN) 2013102883048

(51) Int. Cl. H05K 5/02

(52) U.S. Cl. CPC H05K 5/0221
USPC 403/345

(57) ABSTRACT

A fastening device for fastening a backplane includes an enclosure, a fastening member, and two slide members. The enclosure includes a bottom plate and a top plate. A stop element is formed on the bottom plate and abuts against a front surface of the backplane. Two engaging poles extend down from the top plate. The fastening member is fastened to a top of the backplane. The slide members are slidably connected to the fastening member. Two hooks are formed on rear sides of the slide members and extend toward opposite directions. The hooks engage with the engaging poles.

### BACKGROUND

1. Technical Field

The present disclosure relates to a fastening device for fastening a backplane in place.

2. Description of Related Art

A backplane is configured in a server. Hard disk drives are communicated with a motherboard through the backplane. The backplane is generally fastened to an enclosure of the server by screws. Accordingly, a screwdriver is operated in the enclosure. However, the operation of the screwdriver in the relatively small space of the enclosure is inconvenient.

### BRIEF DESCRIPTION OF THE DRAWINGS

Many aspects of the present embodiments can be better understood with reference to the following drawings. The components in the drawings are not necessarily drawn to scale, the emphasis instead being placed upon clearly illustrating the principles of the present embodiments. Moreover, in the drawings, all the views are schematic, and like reference numerals designate corresponding parts throughout the several views.

FIG. 1 is an exploded, isometric view of an exemplary embodiment of a fastening device together with a backplane, wherein the fastening device includes a fastening member and two slide members.

FIG. 2 is an enlarged view of a circled portion II of FIG. 1.

FIG. 3 is an enlarged view of the fastening member and the slide members of FIG.

1.

FIG. 4 is an inverted view of FIG. 3.

FIG. 5 is an assembled, isometric view of FIG. 1.

FIG. 6 is a front plan view of FIG. 5.

FIG. 7 is a cross-sectional view taken along the line VII-VII of FIG. 6.

### DETAILED DESCRIPTION

The disclosure, including the accompanying drawings, is illustrated by way of example and not by way of limitation. It should be noted that references to “an” or “one” embodiment in this disclosure are not necessarily to the same embodiment, and such references mean “at least one.”

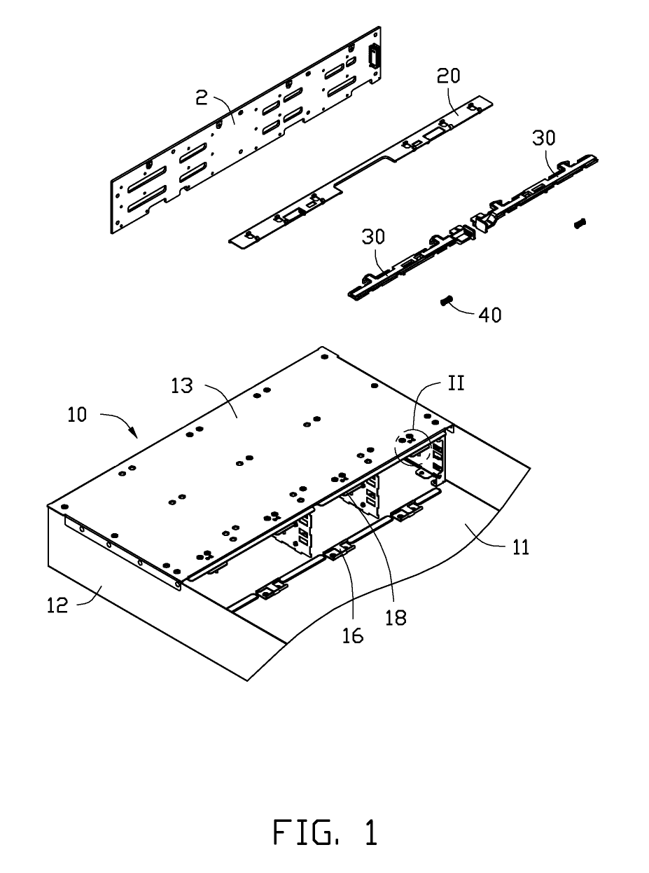

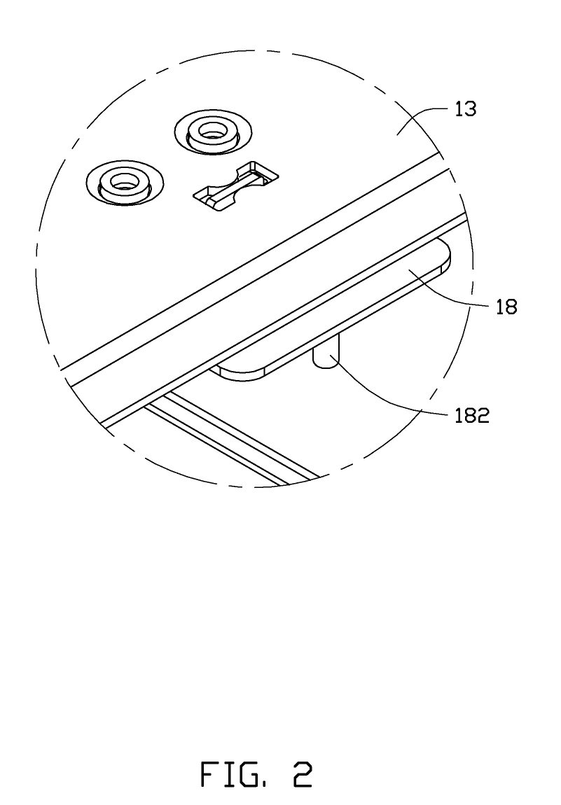

FIGS. 1 and 2 show an exemplary embodiment of a fastening device for fastening a backplane 2. The fastening device includes an enclosure 10, a fastening member 20, two symmetrical slide members 30, and two resilient members 40. In the illustrated embodiment, the resilient members 40 are springs.

The enclosure 10 includes a bottom plate 11, two side plates 12 perpendicularly extending up from opposite sides of the bottom plate 11, and a top plate 13 connected to tops of the side plates 12. Four mounting tabs 18 are fastened to a front side of a bottom of the top plate 13. An engaging pole 182 extends down from each mounting tab 18. A plurality of stop elements 16 is formed on the bottom plate 11.

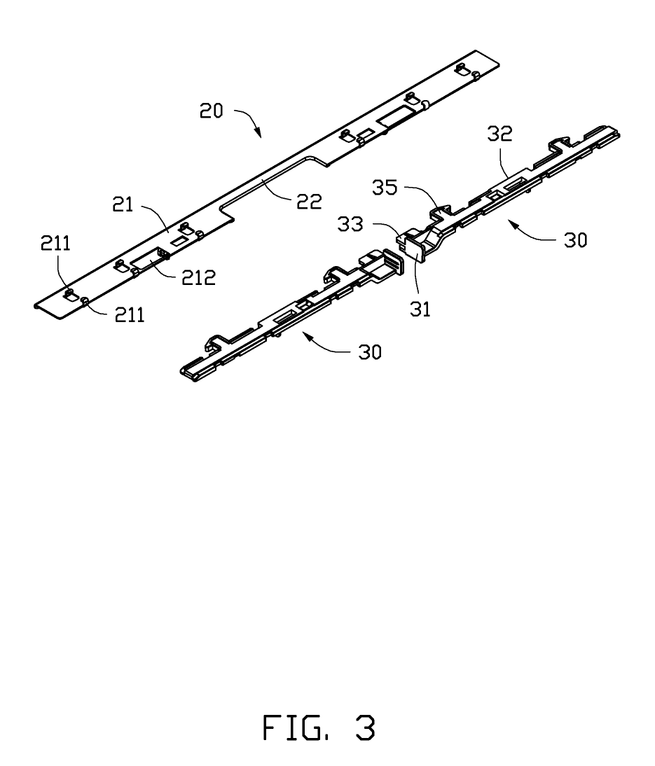

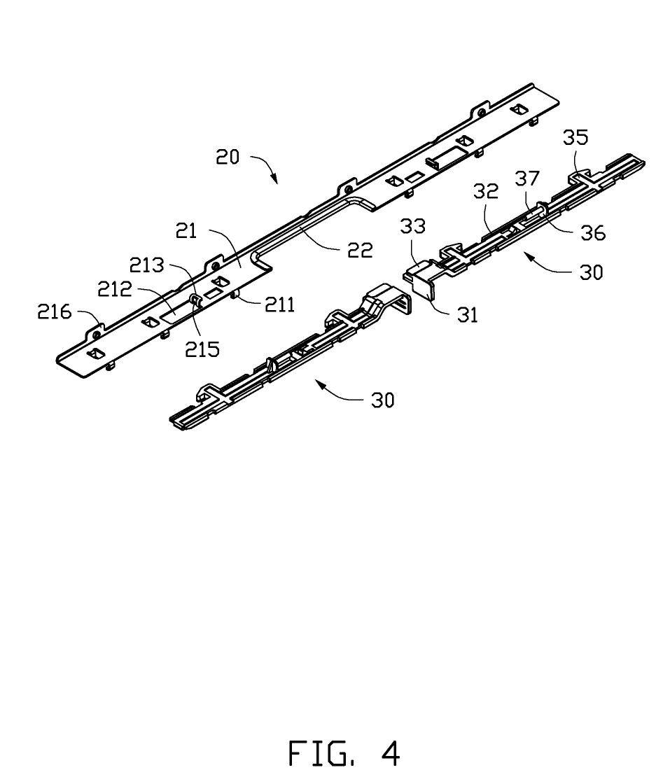

FIGS. 3 and 4 show the fastening member 20 including two symmetrical fastening portions 21 and a connection pole 22 connected between the fastening portions 21. The fastening portions 21 are symmetrical, so only one of the fastening portions 21 is described for giving details. Two rows of clips 211 extend up from the fastening portion 21, arranged along a lengthwise direction of the fastening portion 21. Each clip 211 is substantially L-shaped. The fastening portion 21 defines an opening 212. A stop tab 213 extends down from the fastening portion 21, at an end of the opening 212 near the connection pole 22. The stop tab 213 defines a through hole 215. Two attachment tabs 216 extend down from a side of the fastening portion 21.

The slide members 30 are symmetrical, so only one of the slide members 30 is described for giving details. An operation portion 31 is formed on an end of the slide member 30. Two parallel guiding elements 33 extend from a rear side 32 of the slide member 30, near the operation portion 31. Two hooks 35 extend from the rear side 32 of the slide member 30. Each hook 35 perpendicularly extends from the rear side 32 of the slide member 30 first, and then extends away from the operation portion 31. A block 36 extends down from a middle of the slide member 30. A pin 37 extends from the block 36, and extends toward the operation portion 31.

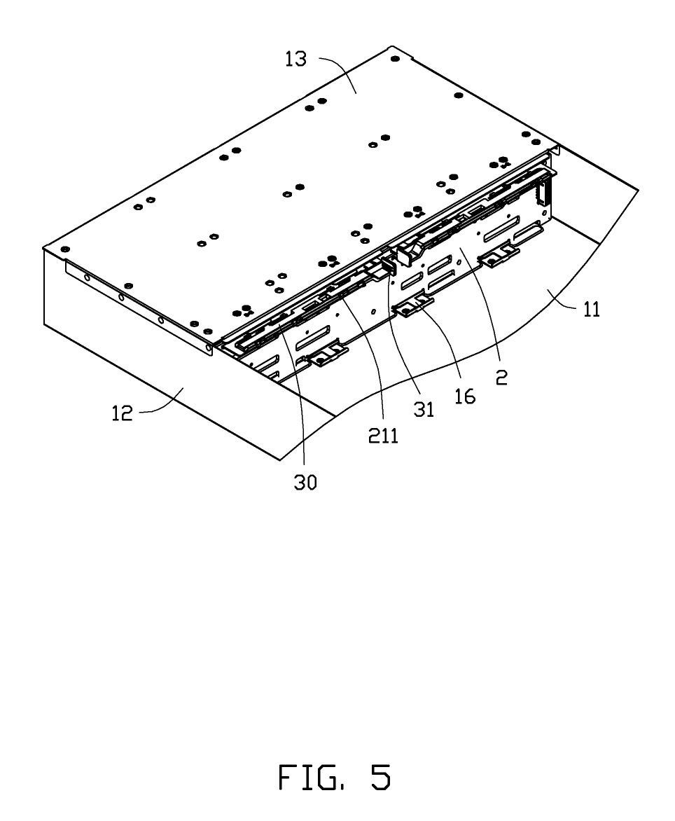

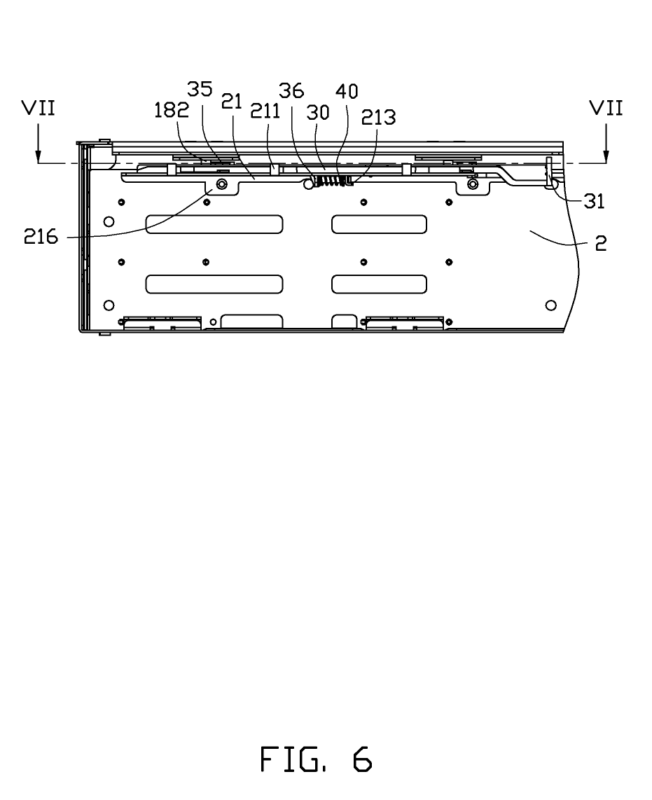

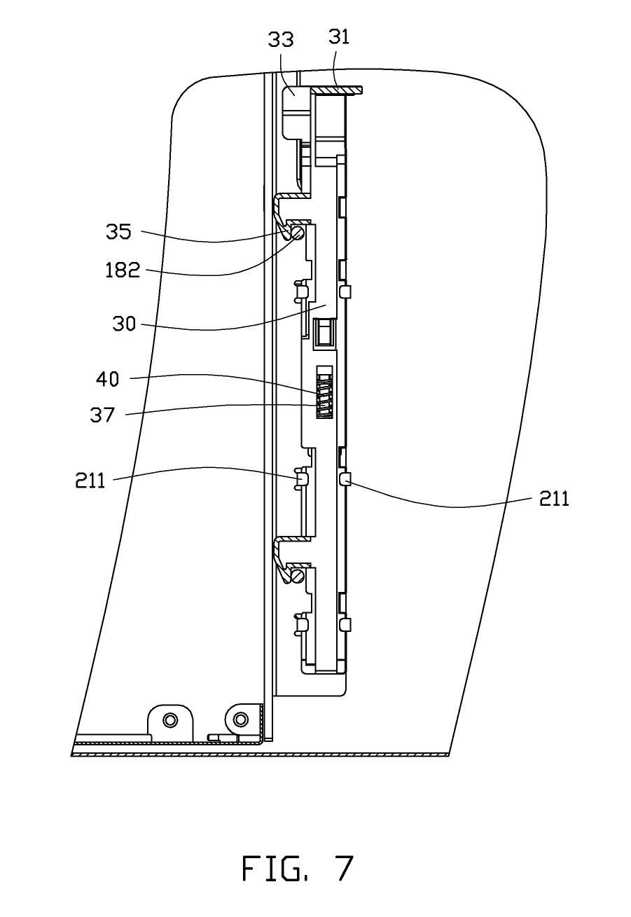

FIGS. 5-7 show in assembly, the attachment tabs 216 are fastened to a top side of the backplane 2 by screws. The two rows of clips 211 are deformed away from each other. The slide members 30 are supported on the corresponding fastening portions 21. The block 36 together with the pin 37 extends through the opening 212. The clips 211 are then released, so that the clips 211 are restored to abut against opposite sides of the slide members 30. Therefore, the slide members 30 are slidably connected to the fastening portions 21. The operation portions 31 of the slide members 30 face each other. The guiding elements 33 of each slide member 30 slidably sandwich the connection pole 22. The resilient members 40 are placed around the pins 37. The top of the backplane 2 is inclined forward. The backplane 2 is supported on the bottom plate 11, and is located behind the stop elements 16. The operation portions 31 are manipulated, to make the slide members 30 slide toward each other. The pins 37 extend through the through holes 215.

Each resilient member 40 is deformed by the corresponding block 36 and the corresponding stop tab 213. The backplane 2 is adjusted to be perpendicular to the bottom plate 11. A bottom of the backplane 2 abuts against rear sides of the stop elements 16. The operation portions 31 are released. The resilient members 40 are restored and abut against the blocks 36, to bias the slide members 30 to slide away from each other. The hooks 35 engage with the engaging poles 182. Thereby, the backplane 2 is fastened to the enclosure 10.

After the fastening member 20 of the fastening device is fastened to the top side of the backplane, the slide members 30 are slidably connected to the fastening member 20. The operator just slides the slide members 30, the backplane 2 is then fastened in place by the hooks 35 engaging with the engaging poles 182, which is convenient.

Even though numerous characteristics and advantages of the embodiments have been set forth in the foregoing description, together with details of the structure and the functions of the embodiments, the disclosure is illustrative only, and changes may be made in details, especially in the matters of shape, size, and arrangement of parts within the principles of the embodiments to the full extent indicated by the broad general meaning of the terms in which the appended claims are expressed.

What is claimed is:

1. A fastening device for fastening a backplane, comprising:
an enclosure comprising a bottom plate and a top plate, the bottom plate forming a stop element for abutting against a front surface of the backplane, two engaging poles extending down from the top plate;
a fastening member to be fastened to a top side of the backplane; and
two slide members slidably connected to the fastening member, two hooks formed on rear sides of the slide members and extending toward opposite directions, the hooks engaging with the engaging poles.

2. The fastening device of claim 1, wherein the fastening member comprises two symmetrical fastening portions and a connection pole connected between the fastening portions, the slide members are slidably connected to the corresponding fastening portions.

3. The fastening device of claim 2, wherein each fastening portion comprises two rows of clips slidably sandwiches the corresponding slide member.

4. The fastening device of claim 2, further comprising two resilient members each mounted between a corresponding one of the fastening portions and the corresponding slide member.

5. The fastening device of claim 4, wherein the fastening portion comprises a stop tab, the stop tab defines a through hole, the slide member comprises a block and a pin extending from the block, the pin extends through the through hole, the resilient member is placed around the pin and is sandwiched between the stop tab and the block.

6. The fastening device of claim 5, wherein the fastening portion defines an opening, the stop tab extends from the fastening portion and at an end of the opening, the block extends through the opening.

7. The fastening device of claim 2, wherein each slide member forms an operation portion near the other slide member.

8. The fastening device of claim 7, wherein each slide member forms two parallel guiding elements slidably sandwiching the connection pole.
